(19) United States
(12) Patent Application Publication
(10) Pub. No.: US 2016/0227668 A1
(43) Pub. Date: Aug. 4, 2016

(54) COOLING MODULE AND HEAT SINK

(71) Applicant: AIC INC., Taoyuan Hsien (TW)

(72) Inventors: Wei-Te WANG, Taoyuan Hsien (TW); Chi-Yuan Hsiao, Taoyuan Hsien (TW); Yao-Sheng GUO, Taoyuan Hsien (TW)

(21) Appl. No.: 14/611,173

(22) Filed: Jan. 31, 2015

(51) Int. Cl. H05K 7/20

(52) U.S. Cl. CPC H05K 7/2039

(57) ABSTRACT

A heat sink includes a base and a removable air guide member. The base includes a thermal plate and two air guide plates fixed to opposite two sides of the thermal plate. An air guide channel is formed between the thermal plate and the two air guide plates. The fins are connected to the thermal plate. One end of each air guide plate bends and extends to form a windshield while another end has a connection portion. The removable air guide member is detachably connected to the base. The removable air guide member includes two vertical plates. One end of each vertical plate is connected to the connection portion while another end bends outward and extends to form a horizontal plate. Thereby, the cooling module and the heat sink can be installed on a motherboard with electronic components arranged densely and may receive maximum airflow.

### TECHNICAL FIELD

The disclosure relates to a heat sink, more particularly to a cooling module and a heat sink.

### BACKGROUND

With today's technology, a large amount of electronic components can be installed on a motherboard densely. The motherboard of an industrial computer, for example, is with multiple CPUs (Central Processing Units) installed thereon and arranged side by side and with multiple memory slots arranged on two sides of the CPU. This may improve the performance and expansion capability of the motherboard.

However, the trend of today's motherboards is to manufacture them as small as possible. This makes the CPUs and the memory slots be arranged even more densely. Closely arranged CPUs lead to an issue of heat dissipation which affects the operation of CPUs negatively. Thus, it is important to find a way to install a heat sink on the motherboard with these densely arranged electronic components.

The objective of the disclosure is to provide an improved design capable of solving the problems mentioned above.

### SUMMARY

The goal of this disclosure is to provide an improved cooling module and a heat sink. In the ideal cooling module and heat sink, the base and the removable air guide member may be assembled together and be disassembled. This enables the cooling module and the heat sink to be installed on the motherboard with electronic components arranged densely. Moreover, the base and the removable air guide member are able to guide airflow into the air guide channel so that the cooling module and the heat sink receive maximum airflow.

To reach the goal, a heat sink is provided and it comprises a base and a removable air guide member. The base comprises a thermal plate and two air guide plates fixed to opposite two sides of the thermal plate. An air guide channel is formed between the thermal plate and the two air guide plates. The plurality of fins is connected to the thermal plate. One end of each of the air guide plates bends and extends to form a windshield while another end has a connection portion. The removable air guide member is detachably connected to the base. The removable air guide member comprises two vertical plates. One end of each of the vertical plates is connected to the connection portion while another end bends outward and extends to form a horizontal plate

Moreover, a cooling module comprises two bases and a removable air guide member. Each of the bases comprises a thermal plate and two air guide plates fixed to opposite two sides of the thermal plate. An air guide channel is formed between the thermal plate and the two air guide plates. A plurality of first fins is connected to one of the thermal plates while a plurality of second fins is connected to the other thermal plate. One end of each of the air guide plates bends outward and extends to form a windshield. Another end of one of the two opposite air guide plates has a connection portion correspondingly. The removable air guide member is disposed between the two bases. The removable air guide member comprises two vertical plates. One end of each of the vertical plates is connected to the connection portion while another end bends outward and extends to form a horizontal plate.

### BRIEF DESCRIPTION OF THE DRAWINGS

The disclosure will become more fully understood from the detailed description and the drawings given herein below for illustration only, and thus does not limit the disclosure, wherein:

FIG. 1 is an exploded view of a heat sink according to a first embodiment of the disclosure;

FIG. 2 is a perspective view of the assembly of the heat sink according to the first embodiment of the disclosure;

FIG. 3 is a top view of the assembly of the heat sink according to the first embodiment of the disclosure;

FIG. 4 is a sectional view of a heat sink according to a second embodiment of the disclosure;

FIG. 5 is a sectional view of a heat sink according to a third embodiment of the disclosure;

FIG. 6 is a sectional view of a heat sink according to a fourth embodiment of the disclosure;

FIG. 7 is a sectional view of a heat sink according to a fifth embodiment of the disclosure;

FIG. 8 is a sectional view of a heat sink according to a sixth embodiment of the disclosure;

FIG. 9 is a sectional view of a heat sink according to a seventh embodiment of the disclosure;

FIG. 10 is an exploded view of a cooling module according to the first embodiment of the disclosure;

FIG. 11 is a perspective view of the assembly of the cooling module according to the first embodiment of the disclosure;

FIG. 12 is a schematic view of the cooling module in use according to the first embodiment of the disclosure;

FIG. 13 is another schematic view of the cooling module in use according to the first embodiment of the disclosure;

FIG. 14 is still another schematic view of the cooling module in use according to the first embodiment of the disclosure;

FIG. 15 is a schematic view of a cooling module in use according to the second embodiment of the disclosure;

FIG. 16 is a schematic view of a cooling module in use according to the third embodiment of the disclosure;

FIG. 17 is an exploded view of the cooling module according to the eighth embodiment of the disclosure;

FIG. 18 is a perspective view of the cooling module according to the eighth embodiment of the disclosure;

FIG. 19 is an exploded view of the cooling module according to the ninth embodiment of the disclosure; and

FIG. 20 is a perspective view of the cooling module according to the ninth embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

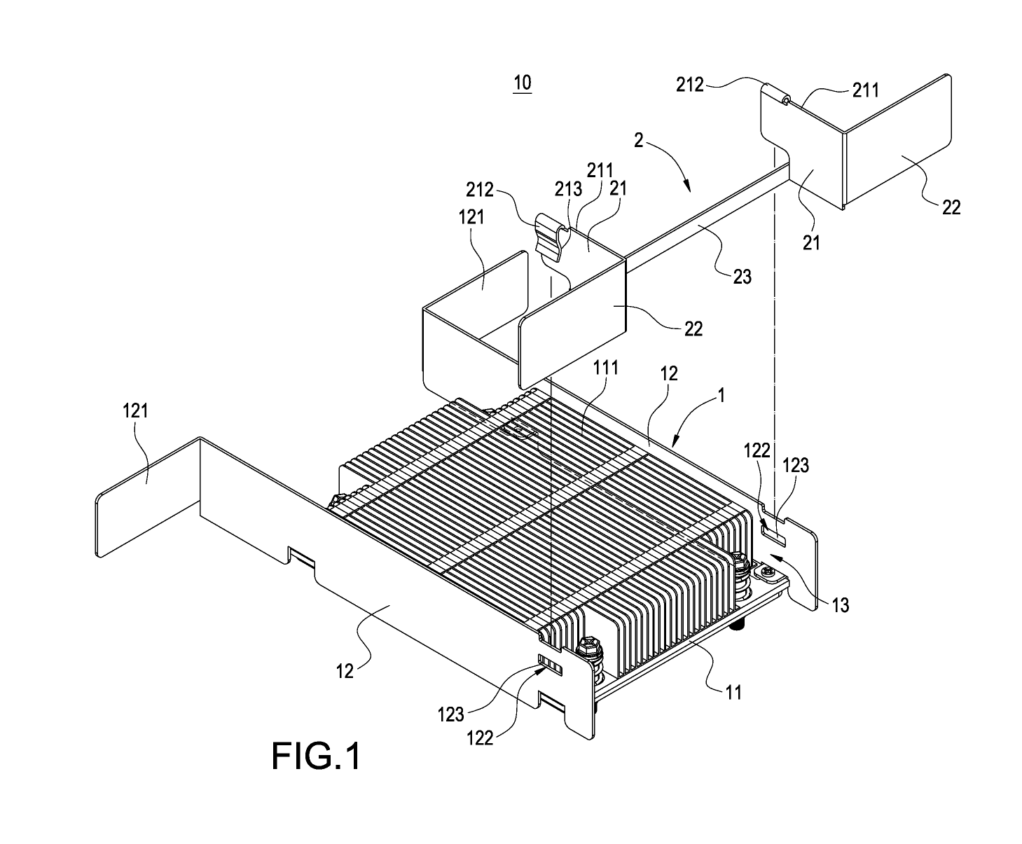

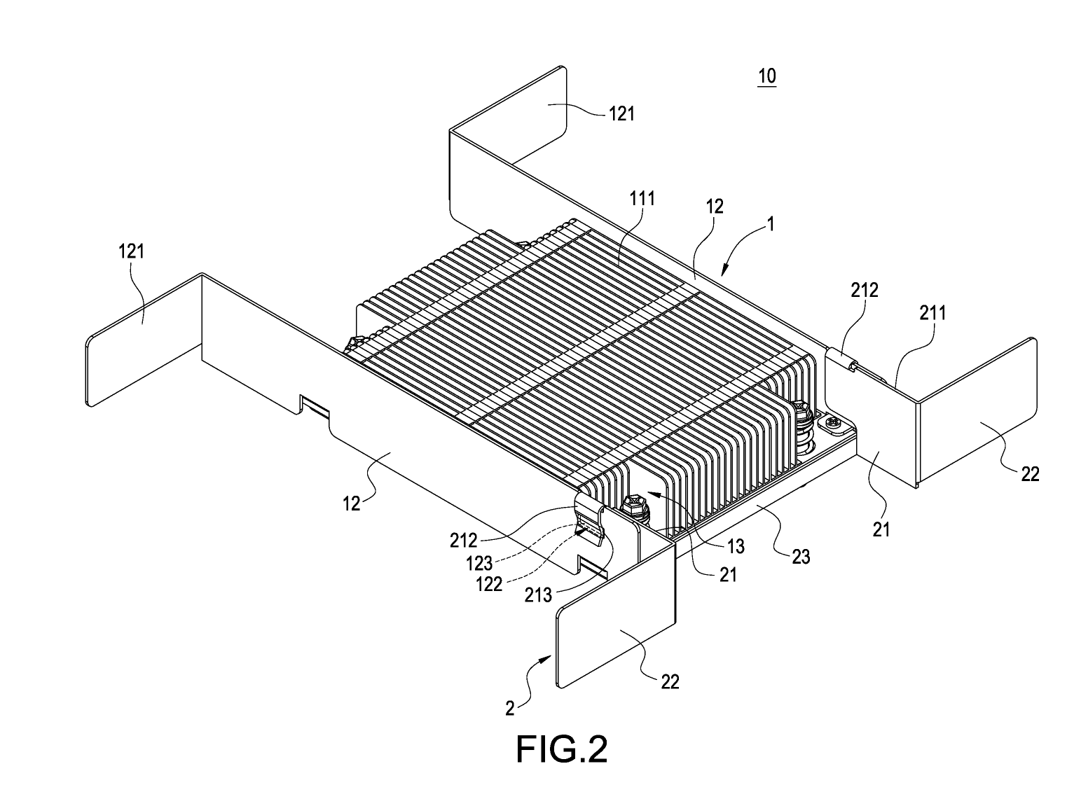

Referring to FIG. 1 to FIG. 3, the disclosure relates to a heat sink 10 comprising a base 1 and a removable air guide member 2.

The base 1 comprises a thermal plate 11 and two air guide plates 12 fixed to opposite two sides of the thermal plate 11. An air guide channel 13 is formed between the thermal plate 11 and the two air guide plates 12. A plurality of fins 111 is connected to the thermal plate 11. One end of each air guide plate 12 bends outward and forms a windshield 121 while another end has a connection portion 122.

Specifically, each connection portion 122 comprises a fastening groove 123 formed on the air guide plate 12 and each fin 111 is disposed in the air guide channel 13. The angle θ1 between each air guide plate 12 and the windshield 121 ranges from 90 degrees to 150 degrees. In this embodiment, the angle θ1 between each air guide plate 12 and the windshield 121 is 90 degrees, but it is not limited thereto.

The removable air guide member 2 is detachably connected to the base 1 and comprises two vertical plates 21. One end of each vertical plate 21 is connected to the connection portion 122 while the other end bends outward and extends to form a horizontal plate 22.

Furthermore, the removable air guide member 2 comprises a crossbar 23 and two vertical plates 21 are fixed to two ends of the crossbar 23. The top portion 211 of each vertical plate 21 extends and folds to form an elastic sheet 212. Each elastic sheet 212 has a protruding portion 213 and each protruding portion 213 is fastened with each fastening groove 123. Additionally, the angle θ2 between each vertical plate 21 and the horizontal plate 22 is 90 degrees.

In the assembly of the heat sink 10, the base 1 comprises the thermal plate 11 and the air guide plates 12 fixed to opposite two sides of the thermal plate 11; the air guide channel 13 is formed between the thermal plate 11 and two air guide plates 12; the plurality of fins 111 is connected to the thermal plate 11; one end of each air guide plate 12 bends outward and forms the windshield 121 while another end has the connection portion 122; the removable air guide member 2 is detachably connected to the base 1 and comprises two vertical plates 21; one end of each vertical plate 21 is connected to the connection portion 122 while the other end bends outward and extends to form the horizontal plate 22. Thereby, the base 1 and the removable air guide member 2 may be assembled together and be disassembled. This enables the heat sink 10 to be installed on the motherboard with electronic components arranged densely. Moreover, the base 1 and the removable air guide member 2 are able to guide airflow into the air guide channel 13 so that the heat sink 10 receives maximum airflow, thereby improving the efficiency of heat dissipation regarding the heat sink 10.

Additionally, the shape of the heat sink 10 is similar to a plate. In other words, the heat sink 10 is thin and may be fixed to most places (e.g. on a motherboard or a computer case).

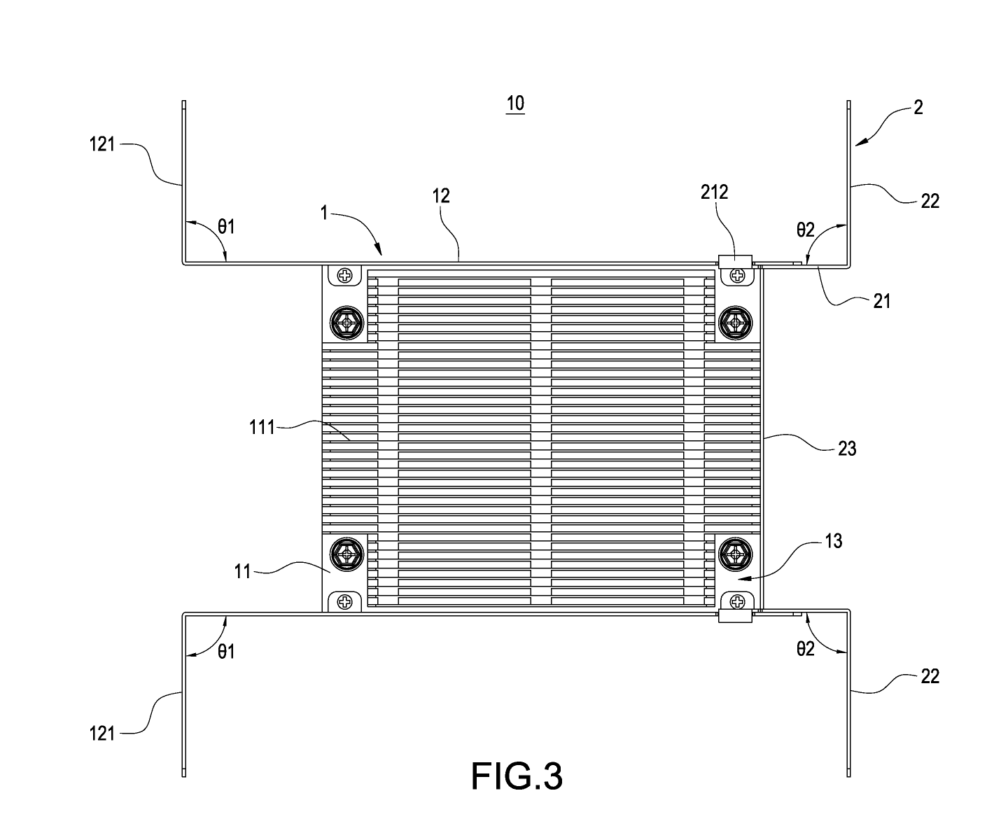

Referring to FIG. 3 to FIG. 6, the heat sinks 10 of the second, third and fourth embodiments are similar to that of the first embodiment but they further comprise a heat pipe 3.

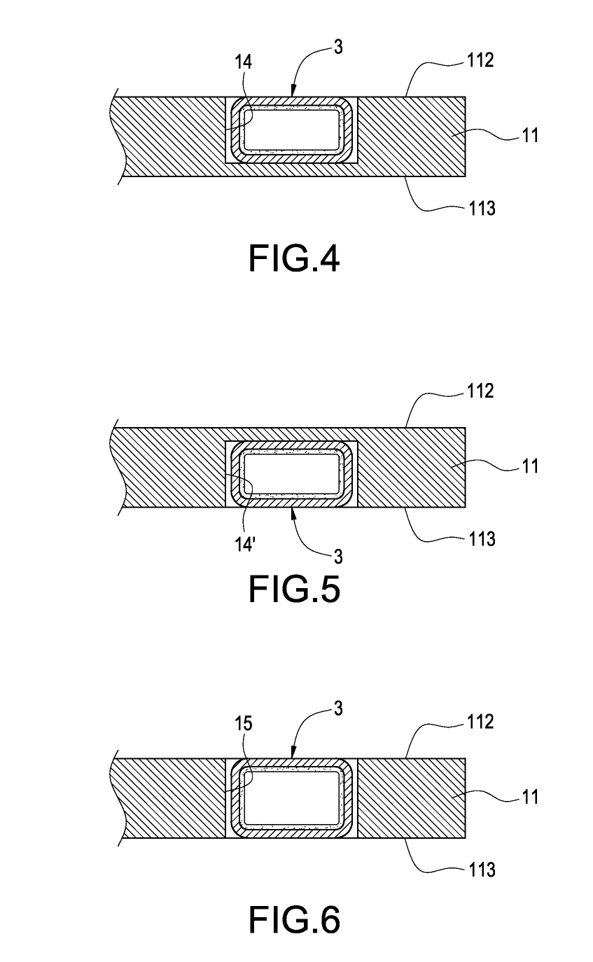

FIG. 4 shows the heat sink 10 of the second embodiment. In FIG. 4, the thermal plate 11 has a top surface 112. A recessed groove 14 is formed on the top surface 112 while the heat pipe 3 is mounted on the recessed groove 14. FIG. 5 shows the heat sink 10 of the third embodiment. In FIG. 5, the thermal plate 11 has a bottom surface 113. A recessed groove 14′ is formed on the bottom surface 113 and the heat pipe 3 is mounted on the recessed groove 14′. FIG. 6 shows the heat sink 10 of the fourth embodiment. In FIG. 6, the thermal plate 11 has a top surface 112 and a bottom surface 113. A through groove 15 penetrating the top surface 112 and the bottom surface 113 is formed on the thermal plate 11. The heat pipe 3 is mounted on the through groove 15. Since the heat pipe 3 is mounted on the thermal plate 11, the efficiency of heat dissipation regarding the heat sink 10 is improved.

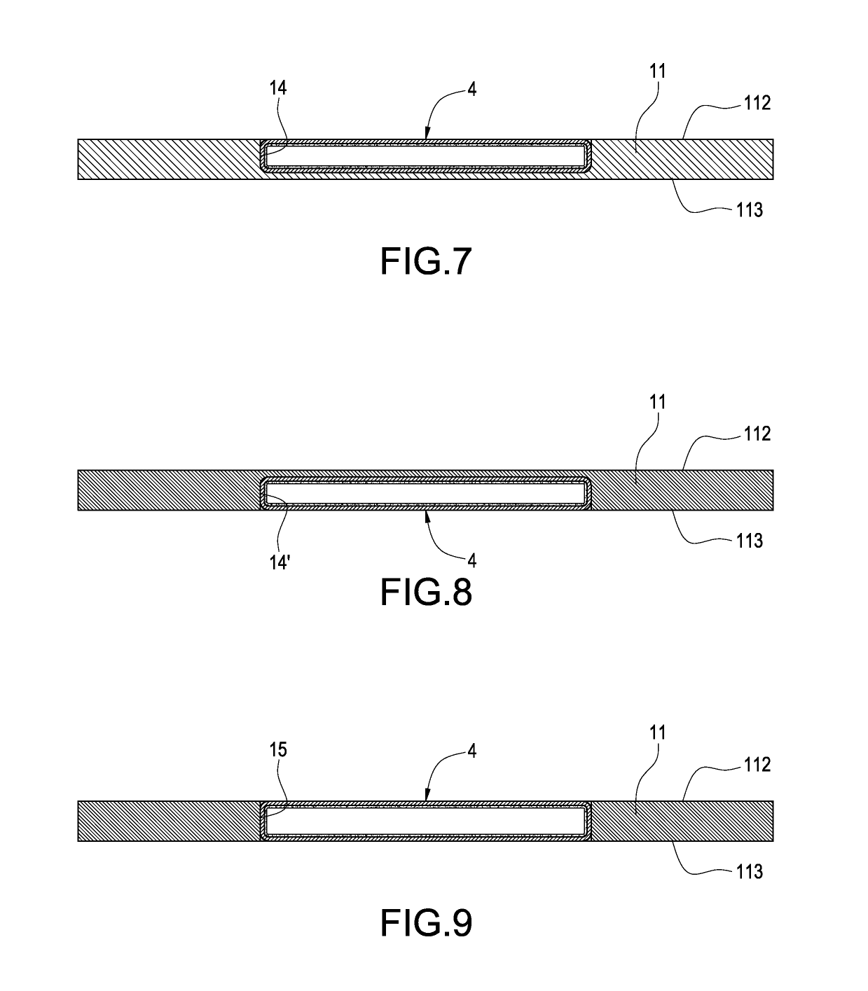

As seen in FIG. 7 to FIG. 9, the heat sinks 10 of the fifth, sixth and seventh embodiments are similar to that of the first embodiment but they further comprise a vapor chamber 4.

Specifically, FIG. 7 shows the heat sink 10 of the fifth embodiment. In FIG. 4, the thermal plate 11 has a top surface 112. A recessed groove 14 is formed on the top surface 112 while the vapor chamber 4 is mounted on the recessed groove 14. FIG. 8 shows the heat sink 10 of the sixth embodiment. In FIG. 8, the thermal plate 11 has a bottom surface 113. A recessed groove 14′ is formed on the bottom surface 113 and the vapor chamber 4 is mounted on the recessed groove 14′. FIG. 9 shows the heat sink 10 of the seventh embodiment. In FIG. 9, the thermal plate 11 has a top surface 112 and a bottom surface 113. A through groove 15 penetrating the top surface 112 and the bottom surface 113 is formed on the thermal plate 11. The vapor chamber 4 is mounted on the through groove 15. Since the vapor chamber 4 is mounted on the thermal plate 11, the efficiency of heat dissipation of the heat sink 10 is improved.

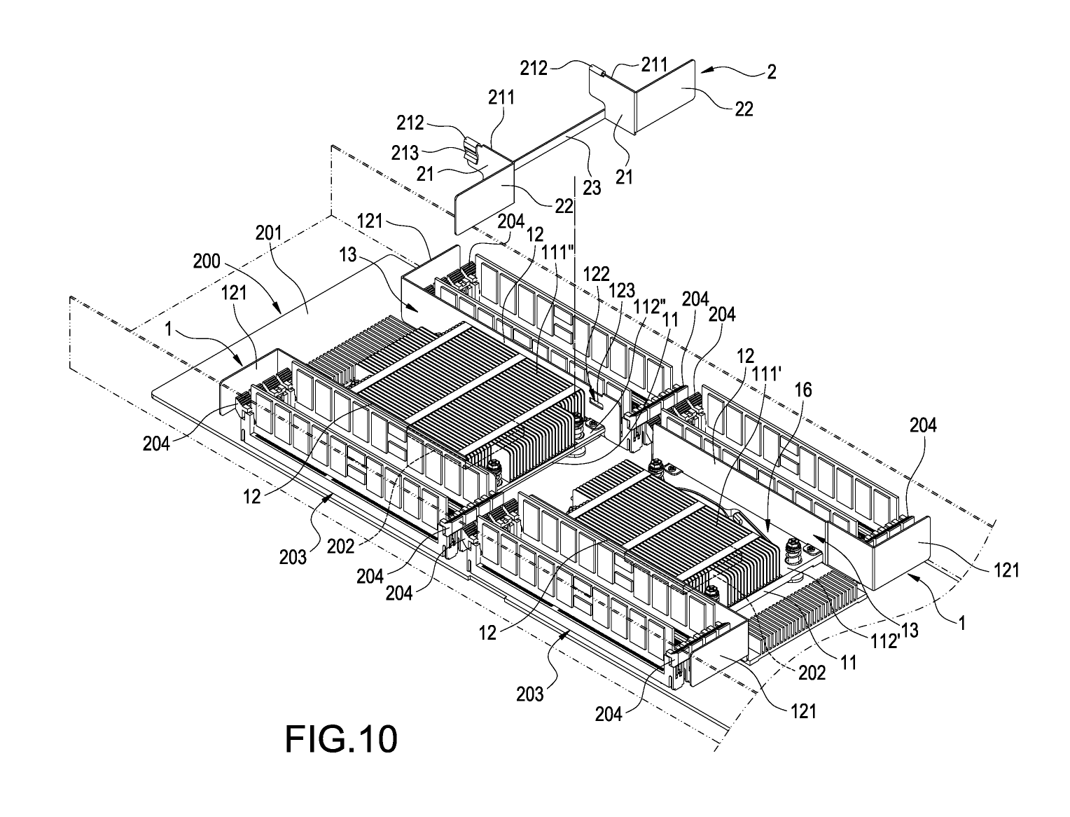

Referring to FIG. 10 to FIG. 14, the disclosure provides a cooling module. The cooling module 100 comprises two bases 1 and a removable air guide member 2.

Each base 1 comprises a thermal plate 11 and two air guide plates 12 fixed to and connected with opposite two sides of the thermal plate 11. An air guide channel 13 is formed between the thermal plate 11 and the two air guide plates 12. A plurality of first fins 111′ is connected to one of the thermal plate 11 while a plurality of second fins 111″ is connected to the other thermal plate 11. One end of each air guide plate 12 bends outward and extends to form a windshield 121. The other end of one of the two air guide plates 12 has a connection portion 122 correspondingly.

Specifically, each connection portion 122 comprises a fastening groove 123 formed on the air guide plate 12. Each first fin 111 and each second fin 111″ are disposed in the air guide channel 13. The angle θ1 between each air guide plate 12 and the windshield 121 ranges from 90 degrees to 150 degrees. In this embodiment, the angle θ1 between each air guide plate 12 and the windshield 121 is 90 degrees for the best performance, but the disclosure is not limited thereto.

Additionally, one of the thermal plates 11 has a first top surface 112′. Each first fin 111′ is connected to a part of the first top surface 112′. The first top surface 112′ forms a no fin area between each first fin 111′ and one of the air guide plate 12. The other thermal plate 11 has a second top surface 112″ and each second fin 111″ is connected to the whole second top surface 112″.

The removable air guide member 2 is disposed between the two bases 1 and comprises two vertical plates 21. One end of each vertical plate 21 is connected with the connection portion 122 while the other end bends outward and extends to form a horizontal plate 22.

Moreover, the removable air guide member 2 comprises a crossbar 23 and two vertical plates 21 are fixed to two ends of the crossbar 23. Top portion 211 of each vertical plate 21 extends and folds to form an elastic sheet 212. Each elastic sheet 212 has a protruding portion 213 and each protruding portion 213 is fastened with each fastening groove 123. Additionally, the angle θ2 between each vertical plate 21 and the horizontal plate 22 is 90 degrees.

In the assembly of the cooling module 100 of the disclosure, the base 1 comprises the thermal plate 11 and the air guide plates 12 fixed to opposite two sides of the thermal plate 11; the air guide channel 13 is formed between the thermal plate 11 and two air guide plates 12; each first fin 111′ is connected to one of the thermal plate 11 while each second fin 111″ is connected to the other thermal plate 11; one end of each air guide plate 12 bends outward and extends to form the windshield 121; the other end of one of the two air guide plates 12 has the connection portion 122 correspondingly; the removable air guide member 2 is disposed between the two bases 1 and comprises vertical plates 21; one end of each vertical plate 21 is connected with the connection portion 122 while the other end bends outward and extends to form the horizontal plate 22. Thereby, the base 1 and the removable air guide member 2 may be assembled together and be disassembled. This enables cooling module 100 to be installed on the motherboard with electronic components arranged densely. Moreover, the base 1 and the removable air guide member 2 are able to guide airflow into the air guide channel 13 so that the cooling module 100 receives maximum airflow, thereby improving the efficiency of heat dissipation regarding the cooling module 100.

The usage state of the cooling module involves a motherboard 200 and a fan 300. The motherboard 200 comprises a circuit board 201, two CPUs 202 arranged side by side on the circuit board 201 and four memory slots disposed on two sides of each CPU 202. Two ends of each memory slot 203 have two plates 204 while the fan 300 and the motherboard 200 are arranged correspondingly.

Firstly, as seen in FIG. 10, the two bases 1 are fixed to the top of each CPU 202 and between the two memory slots 203. The windshield 121 is arranged along the outside of the memory slot 203.

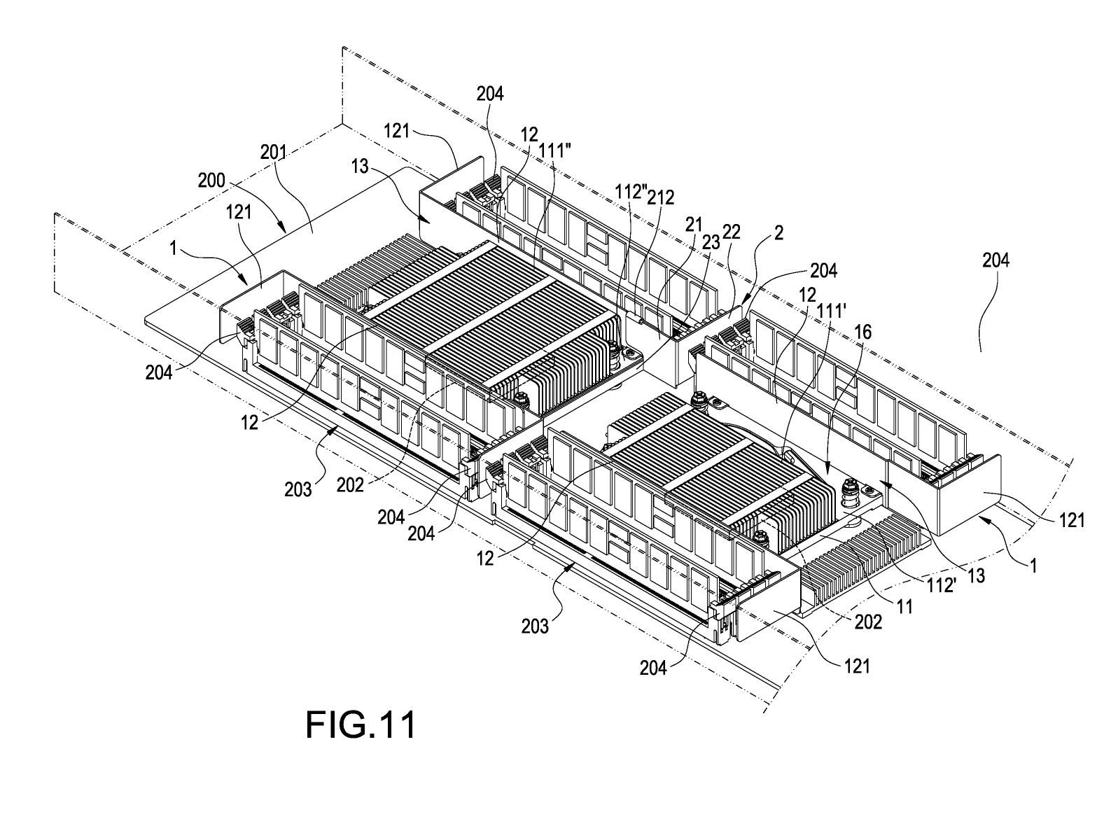

Then, as shown in FIG. 10 to FIG. 11, the removable air guide member 2 is disposed between the two bases 1 while each protruding portion 213 is fastened with each fastening groove 123. Thereby, each vertical plate 21 is detachably connected to the connection portion 122 and the two horizontal plates 22 are disposed between each two memory slots 203.

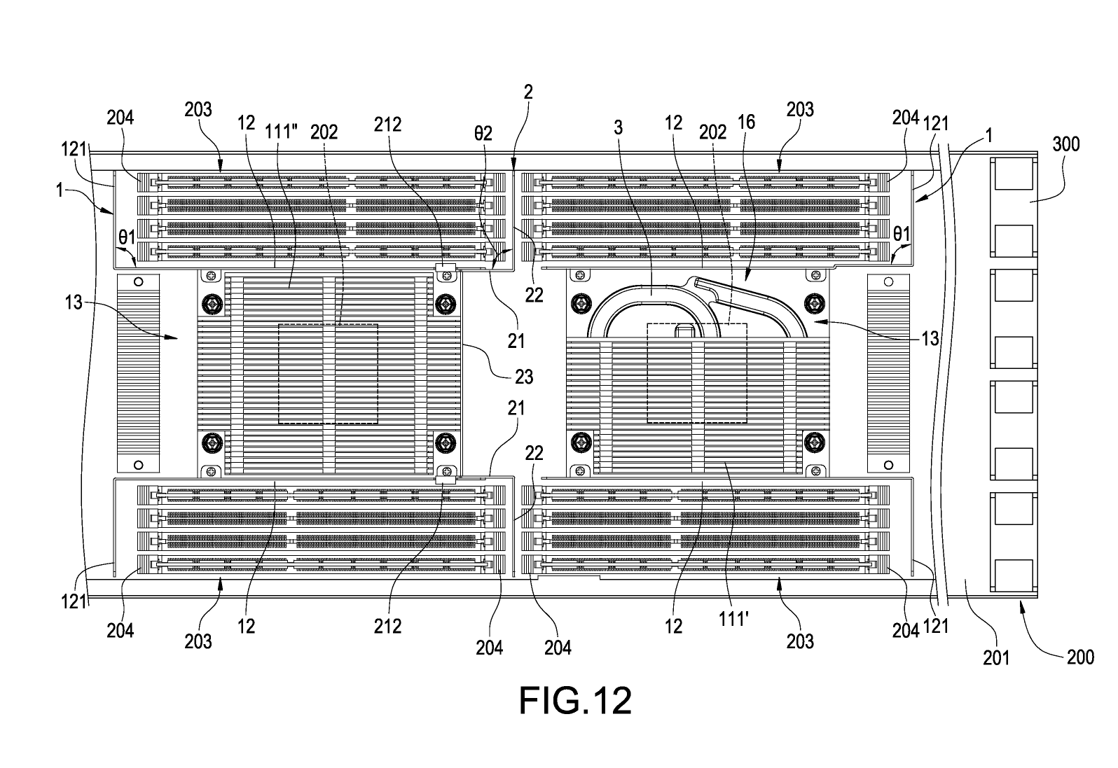

Lastly, referring to FIG. 12, the fan 300 and the air guide channel 13 are arranged correspondingly while the windshield 121 and the removable air guide member 2 fill in the gap between each memory slot 203. Thereby, airflow is reliably guided to the air guide channel 13 and heat of the CPU 202 is transferred to the first fins 111′ as well as the second fins 111″ by airflow and then be dissipated to the outside.

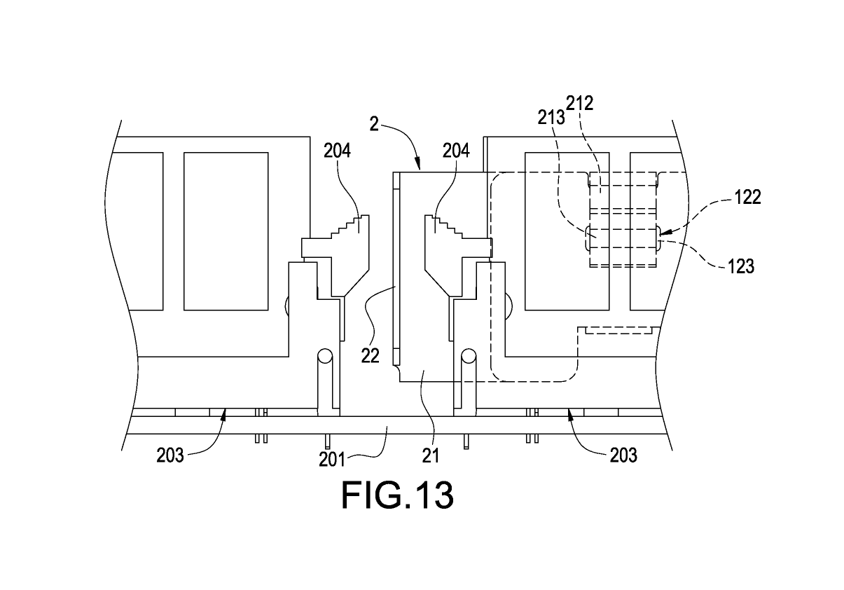

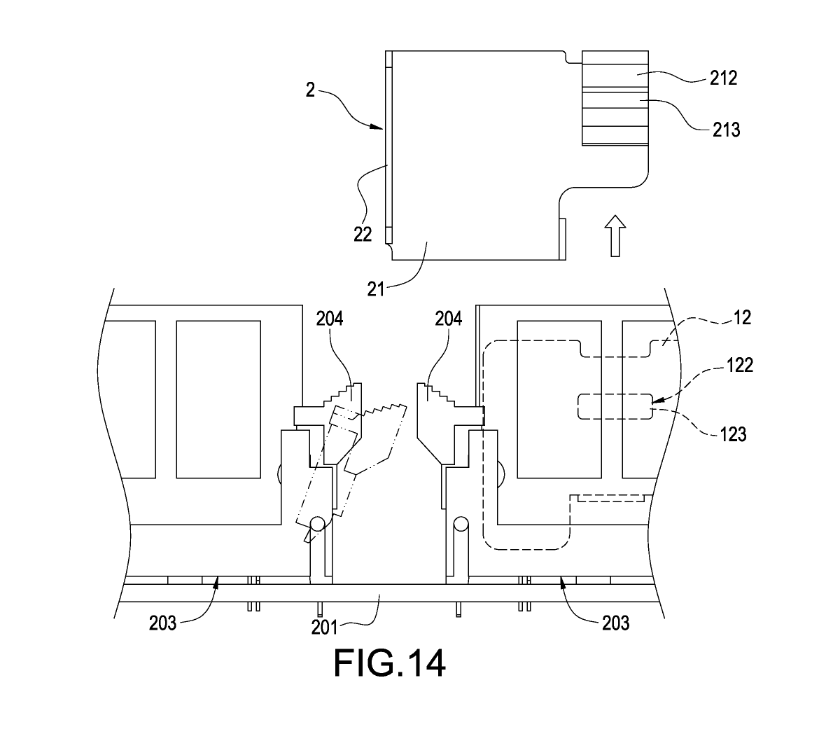

Additionally, as seen in FIG. 13, nowadays the motherboard 200 is manufactured as small as possible so the CPUs 202 and the memory slots 203 are arranged densely. As a result, the gap between the memory slots 203 is approximately equal to the width of the horizontal plate 22 so the plate 204 is unable to be turned and be moved. Nonetheless, as shown in FIG. 14, the removable air guide member 2 and the base 1 can be assembled together and be disassembled. Hence, the plate 204 can be moved and be utilized normally by removing the removable air guide member 2 from the base 1.

Referring to FIG. 12, the fan 300 may be arranged near the first fins 111′ or near the second fins 111″ so it is not limited to the arrangement illustrated in this embodiment. Nonetheless, no matter where the fan 300 is disposed (namely either near the first fins 111′ or near the second fins 111″), it will generate airflow blowing from the first fns 111′ to the second fins 111″. Consequently, the first top surface 112′ forms a no fin area 16 between each first fin 111′ and one of the thermal plate 12, which enables airflow to go from the first fins 111′ to the second fins 111″. This improves the performance of air guide and heat dissipation regarding the cooling module 100.

Similarly, the second top surface 112″ forms a no fin area between each second fin 111″ and one of the thermal plates 12 when the fan 300 generates airflow going from the second fins 111″ to the first fins 111′. This ensures airflow going from the second fins 111″ to the first fins 111′.

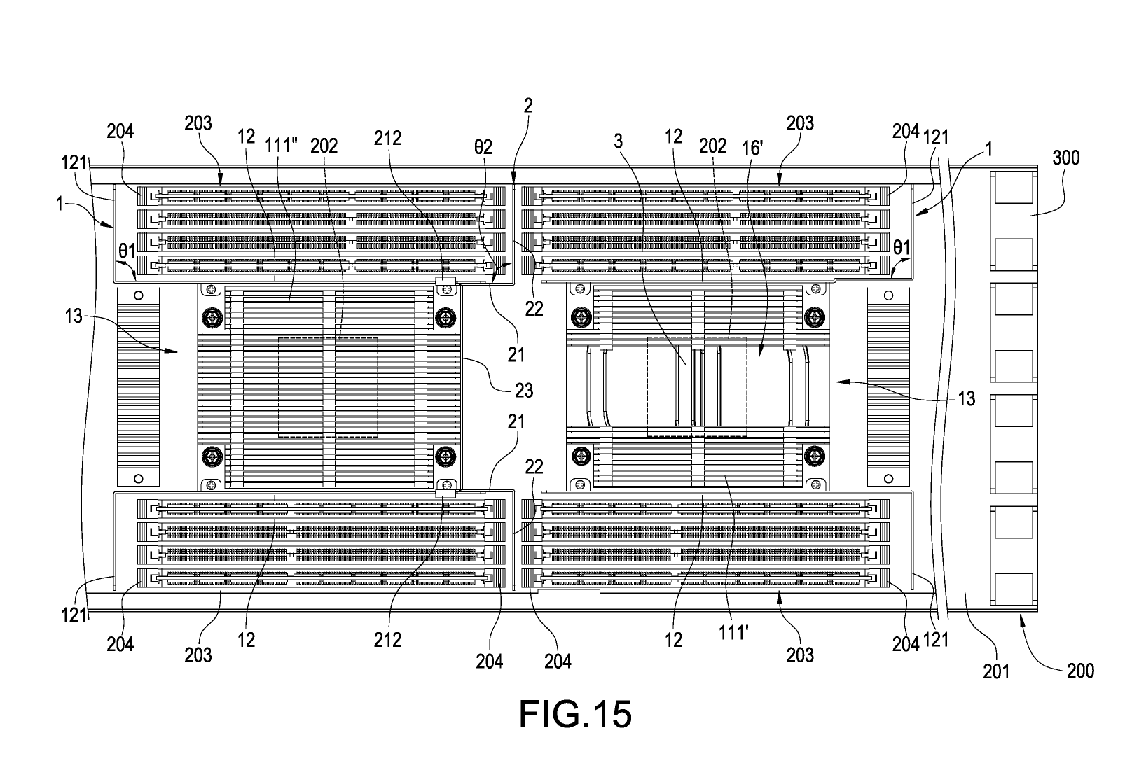

FIG. 15 shows the cooling module 100 of the second embodiment which is similar to that of the first embodiment but with different locations in terms of the no fin area 16′.

Specifically, the fan 300 generates airflow going from the first fins 111′ to the second fins 111″ so each first fin 111′ is connected to two sides of the first top surface 112′ and the first top surface 112′ forms the no fin area 16′ between each first fin 111′. Besides, each second fin 111″ is connected to the whole second top surface 112″. This ensures that airflow is able to go from the first fins 111′ to the second fins 111″.

Similarly, the second top surface 112″ also forms a no fin area between each second fin 111″ and one of the thermal plates 12 when the fan 300 generates airflow going from the second fins 111″ to the first fins 111′. This ensures airflow going from the second fins 111″ to the first fins 111′.

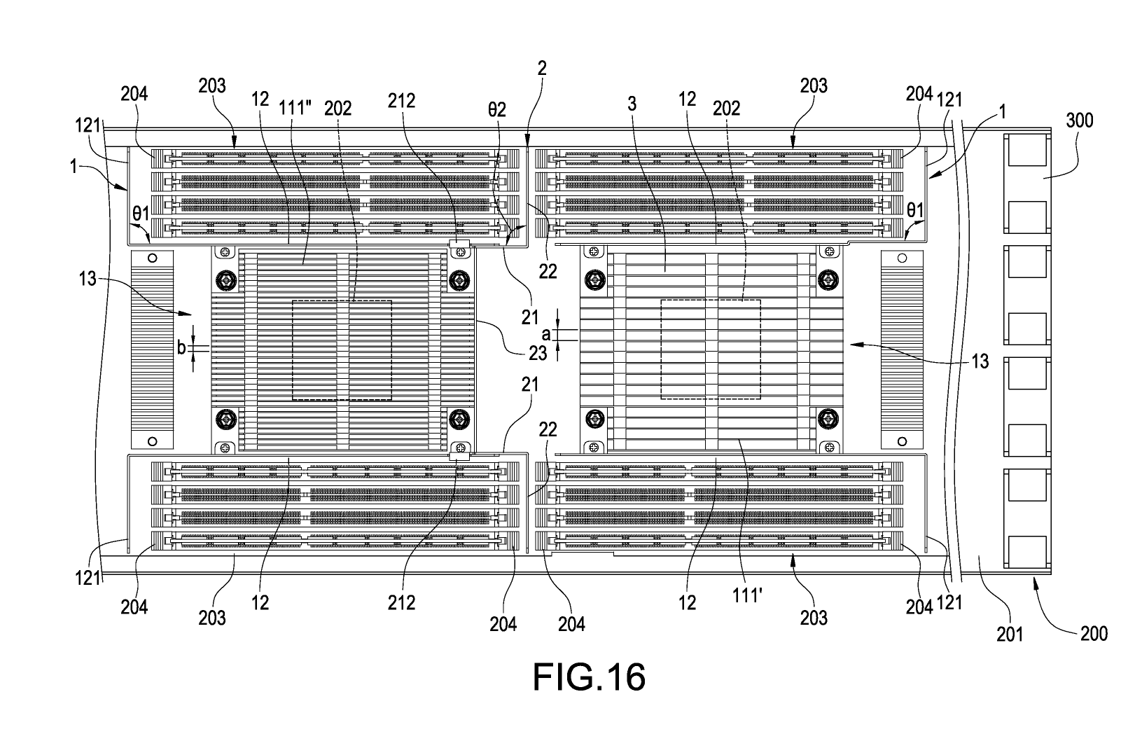

FIG. 16 shows the cooling module 100 of the third embodiment which is similar to that of the first embodiment but it has a distance a between each first fin 111′ greater than a distance b between each second fin 111″.

Specifically, the fan 300 generates airflow going from the first fins 111; to the second fins 111″. Thus, each first fin 111′ is arranged at intervals and connected to the whole first top surface 112′ while each second fin 111″ is arranged at intervals and connected to the whole second top surface 112″. The distance a between the adjacent two first fins 111′ is greater than the distance b between the adjacent two second fins 111″. This ensures that airflow goes from the first fins 111′ to the second fins 111″.

Similarly, the distance a between the adjacent two first fins 111′ is less than the distance b between the adjacent two second fins 111″ when the fan 300 generates airflow going from the second fin 111″ to the first fin 111′. This ensures that airflow goes from the second fins 111″ to the first fins 111′.

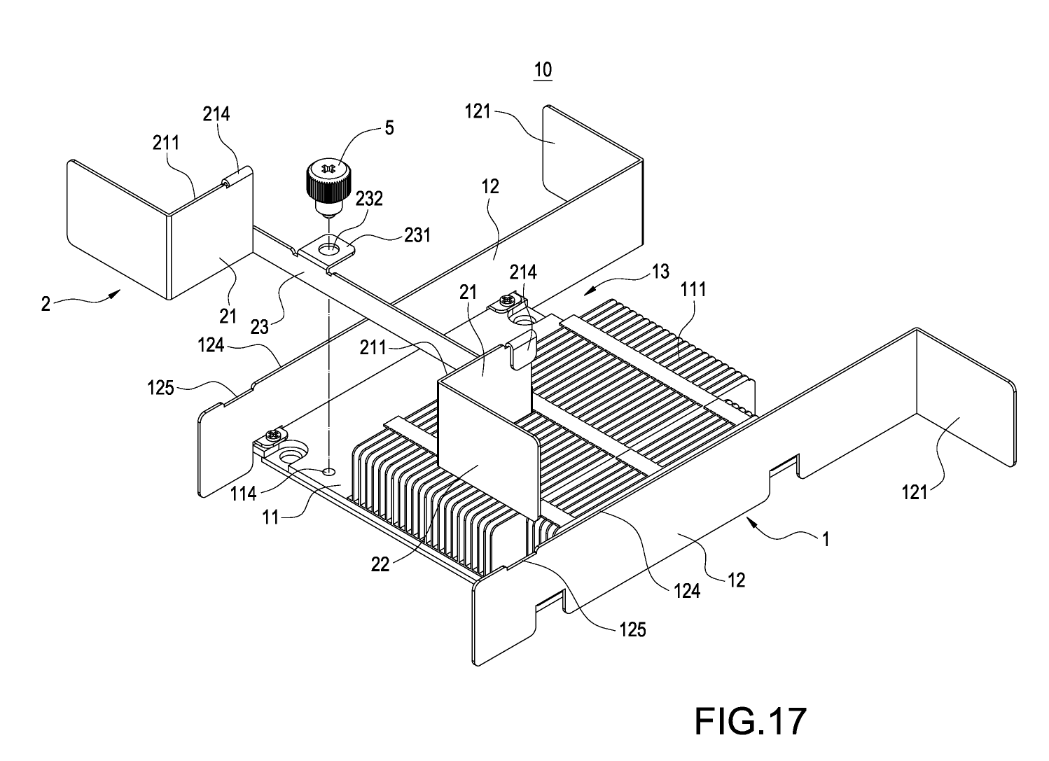

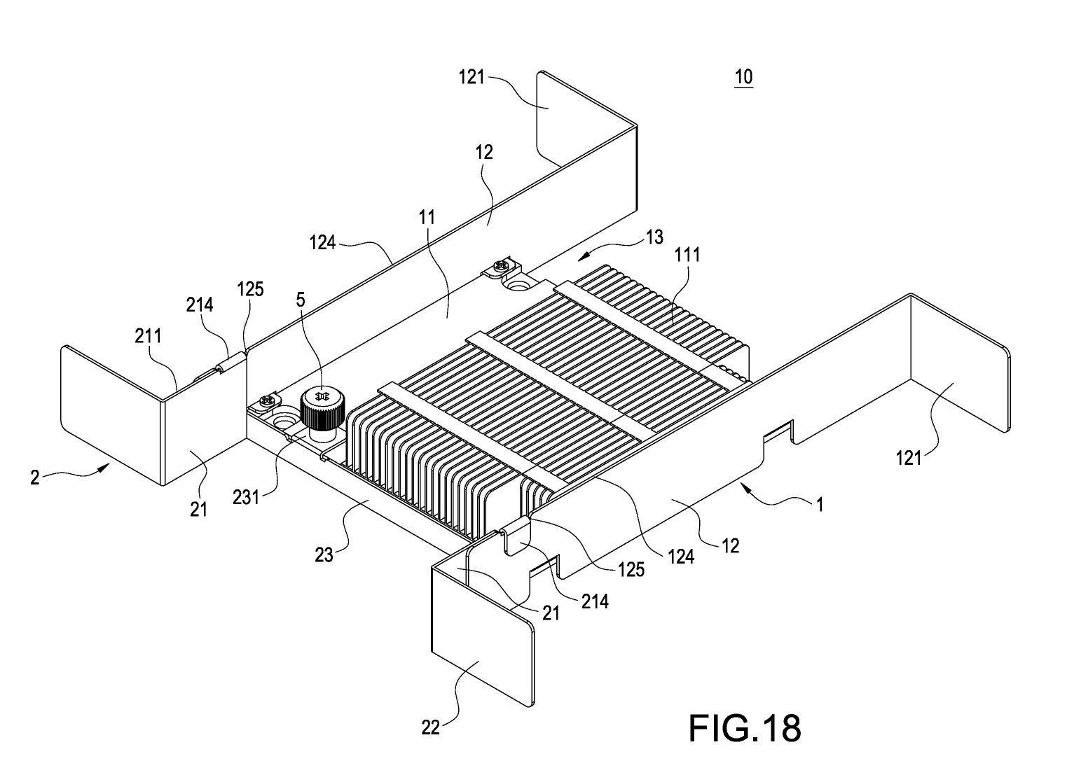

FIG. 17 and FIG. 18 show the heat sink 10 of the eighth embodiment which is similar to that of the first embodiment but the removable air guide member 2 is fixed to the base 1 by locking.

Specifically, the heat sink 10 further comprises a fixing member 5 (e.g. a screw or a fastener). The crossbar 23 extends and forms a protruding piece 231 with a through hole 232 formed thereon. A fixing hole 114 is formed on the thermal plate 11. The fixing member 5 goes through and is fixed to the through hole 232 as well as the fixing hole 114 so that the removable air guide member 2 is fixed to the base 1 by locking.

Furthermore, as seen in FIG. 1 to FIG. 3, each connection portion 122 may comprise the fastening groove 123 formed on the air guide plate 12. As shown in FIG. 17 to FIG. 18, each connection portion 122 may also comprise the mounting groove 125 formed downwardly on the top edge 124 of the air guide plate 12. The top portion 211 of each vertical plate 21 extends and folds to form a barb 214 while each barb 214 and each mounting groove 125 are mounted together.

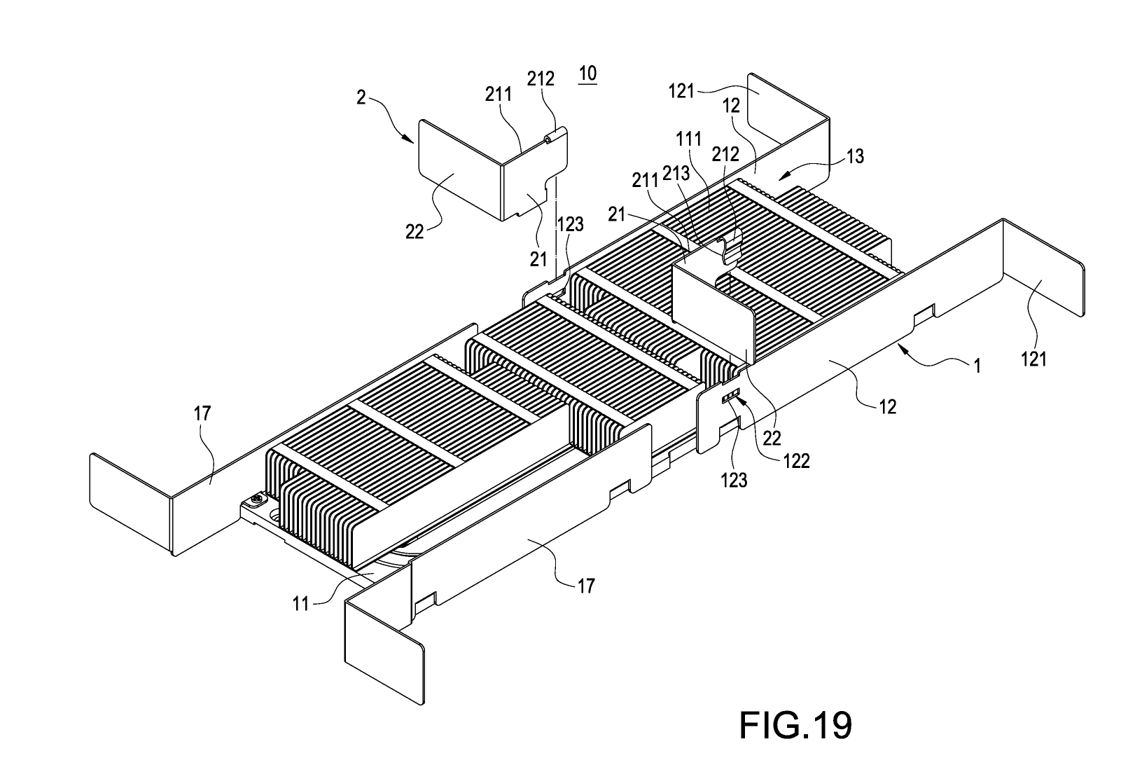

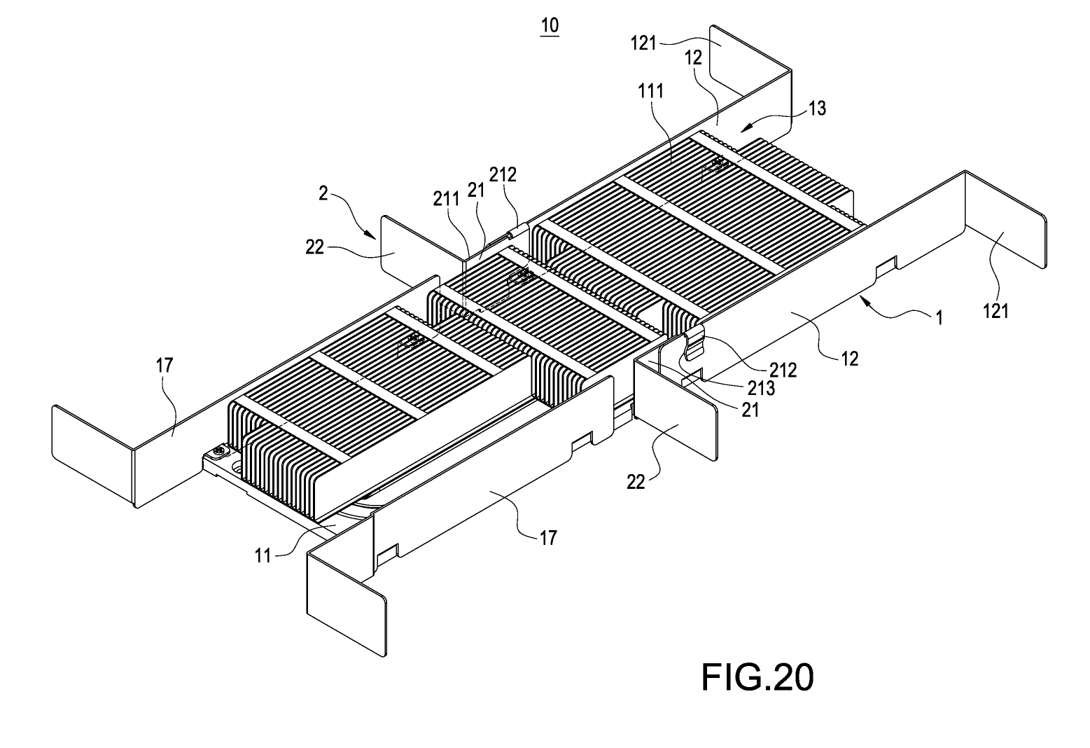

FIG. 19 and FIG. 20 show the heat sink 10 of the ninth embodiment which is similar to that of the first embodiment but the base 1 of this embodiment further comprises two auxiliary air guide plates 17.

Specifically, two auxiliary air guide plates 17 are fixed to opposite two sides of the thermal plate 11 while the two auxiliary air guide plates 17 and the two air guide plates 12 are spaced apart and are arranged side by side. Thereby, the two auxiliary air guide plates 17 and the two air guide plates 12 are on the front side, the rear side, the left side and the right side. Since the two auxiliary air guide plates 17 and the two air guide plates 12 are separated from each other, an opening is therefore between them. The removable air guide member 2 is disposed between the two auxiliary air guide plates 17 and the two air guide plates 12 for covering the opening between the two auxiliary air guide plates 17 and the two air guide plates 12. As a result, the base 1 and the removable air guide member 2 are able to guide airflow into the air guide channel 13 such that the heat sink 10 receives maximum airflow, which improves the heat dissipation efficiency of the heat sink 10.

What is claimed is:

1. A heat sink, comprising
a base (1) comprising a thermal plate (11) and two air guide plates (12) fixed to opposite two sides of the thermal plate (11), wherein an air guide channel (13) is formed between the thermal plate (11) and the two air guide plates (12), a plurality of fins (111) is connected to the thermal plate (11), one end of each of the air guide plates (12) bends and extends to form a windshield (121) while another end has a connection portion (122); and
a removable air guide member (2) detachably connected to the base (1), wherein the removable air guide member (2) comprises two vertical plates (21), one end of each of the vertical plates (21) is connected to the connection portion (122) while another end bends outward and extends to form a horizontal plate (22).

2. The heat sink according to claim 1, wherein each of the connection portion (122) comprises a fastening groove (123) formed on the air guide plate (12), the top portion (211) of each of the vertical plates (21) extends and folds to form an elastic sheet (212), each of the elastic sheets (212) has a protruding portion (213), and each of the protruding portions (213) is fastened with each of the fastening grooves (123).

3. The heat sink according to claim 1, wherein the removable air guide member (2) further comprises a crossbar (23) and the two vertical plates (21) are fixed to two ends of the crossbar (23).

4. The heat sink according to claim 1, wherein an angle between each of the air guide plates (12) and the windshield (121) ranges from 90 degrees to 150 degrees.

5. The heat sink according to claim 1, wherein an angle between each of the vertical plates (21) and the horizontal plate (22) is 90 degrees.

6. The heat sink according to claim 1, further comprising a heat pipe (3), wherein the thermal plate (11) has a top surface (112), a recessed groove (14) is formed on the top surface (112) and the heat pipe (3) is mounted on the recessed groove (14).

7. The heat sink according to claim 1, further comprising a heat pipe (3), wherein the thermal plate (11) has a bottom surface (113), a recessed groove (14) is formed on the bottom surface (113) and the heat pipe (3) is mounted on the recessed groove (14).

8. The heat sink according to claim 1, further comprising a heat pipe (3), wherein the thermal plate (11) has a top surface (112) and a bottom surface (113), a through groove (15) penetrating the top surface (112) and the bottom surface (113) is formed on the thermal plate (11) and the heat pipe (3) is mounted on the through groove (15).

9. The heat sink according to claim 1, further comprising a vapor chamber (4), wherein the thermal plate (11) has a top surface (112), a recessed groove (14) is formed on the top surface (112) and the vapor chamber (4) is mounted on the recessed groove (14).

10. The heat sink according to claim 1, further comprising a vapor chamber (4), wherein the thermal plate (11) has a bottom surface (113), a recessed groove (14′) is formed on the bottom surface (113) and the vapor chamber (4) is mounted on the recessed groove (14′).

11. The heat sink according to claim 1, further comprising a vapor chamber (4), wherein the thermal plate (11) has a top surface (112) and a bottom surface (113), a through groove (15) penetrating the top surface (112) and the bottom surface (113) is formed on the thermal plate (11) and the vapor chamber (4) is mounted on the through groove (15).

12. The heat sink according to claim 3, wherein each of the connection portions (122) comprises a mounting groove (125) formed downwardly on a top edge (124) of the air guide plate (12), the top portion (211) of each of the vertical plates (21) extends and folds to form a barb (214), and each of the barbs (214) is mounted on each of the mounting grooves (125).

13. The heat sink according to claim 3, further comprising a fixing member (5), wherein the crossbar (23) extends to form a protruding piece (231), a through hole (232) is formed on the protruding piece (231), a fixing hole (114) is formed on the thermal plate (11) and the fixing member (5) goes through and is fixed to the through hole (232) and the fixing hole (114).

14. The heat sink according to claim 1, wherein the base (1) further comprises two auxiliary air guide plates (17) fixed to opposite two sides of the thermal plate (11), wherein the two auxiliary air guide plates (17) and the two air guide plates (12) are spaced apart and are arranged side by side, the removable air guide member (2) is disposed between the two auxiliary air guide plates (17) and the two air guide plates (12).

15. A cooling module, comprising
two bases (1), wherein each of the bases (1) comprises a thermal plate (11) and two air guide plates (12) fixed to opposite two sides of the thermal plate (11), an air guide channel (13) is formed between the thermal plate (11) and the two air guide plates (12), a plurality of first fins (111′) is connected to one of the thermal plates (11) while a plurality of second fins (111″) is connected to the other thermal plate (11), one end of each of the air guide plates (12) bends outward and extends to form a windshield (121), and another end of one of the two air guide plates (12) has a connection portion (122) correspondingly; and
a removable air guide member (2) disposed between the two bases (1), wherein the removable air guide member (2) comprises two vertical plates (21), one end of each of the vertical plates (21) is connected to the connection portion (122) while another end bends outward and extends to form a horizontal plate (22).

16. The cooling module according to claim 15, wherein each of the connection portion (122) comprises a fastening groove (123) formed on the air guide plate (12), the top portion (211) of each of the vertical plates (21) extends and folds to form an elastic sheet (212), each of the elastic sheets (212) has a protruding portion (213), and each of the protruding portions (213) is fastened with each of the fastening grooves (123).

17. The cooling module according to claim 15, wherein the removable air guide member (2) further comprises a crossbar (23) and the two vertical plates (21) are fixed to two ends of the crossbar (23).

18. The cooling module according to claim 15, wherein an angle between each of the air guide plates (12) and the windshield (121) ranges from 90 degrees to 150 degrees.

19. The cooling module according to claim 15, wherein an angle between each of the vertical plates (21) and the horizontal plate (22) is 90 degrees.

20. The cooling module according to claim 15, wherein one of the thermal plates (11) has a first top surface (112′), the first fins (111′) are connected to a part of the first top surface (112′), the first top surface (112′) forms a no fin area (16) between the first fins (111′) and one of the thermal plates (11), the other thermal plate (11) has a second top surface (112″) and the second fins (111″) are connected to the whole second top surface (112″).

21. The cooling module according to claim 15, wherein one of the thermal plates (11) has a first top surface (112′), the first fins (111′) are connected to two sides of the first top surface (112′), the first top surface (112′) forms a no fin area (16) between the first fins (111′), the other thermal plate (11) has a second top surface (112″) and the second fins (111″) are connected to the whole second top surface (112″).

22. The cooling module according to claim 15, wherein one of the thermal plates (11) has a first top surface (112′), the first fins (111′) which are positioned at intervals are connected to the whole first top surface (112′), the other thermal plate (11) has a second top surface (112″), the second fins (111″) which are positioned at intervals are connected to the whole second top surface (112″), and a distance (a) between the adjacent two first fins (111′) is greater than a distance (b) between the adjacent two second fins (111″).
